(19) United States
(12) Patent Application Publication
(10) Pub. No.: US 2013/0139753 A1
(43) Pub. Date: Jun. 6, 2013

(54) APPARATUS FOR MANUFACTURING SUBSTRATE

(71) Applicants: Joon Seok Kang, Gyunggi-do (KR); Seung Wan Shin, Gyunggi-do (KR)

(72) Inventors: Joon Seok Kang, Gyunggi-do (KR); Seung Wan Shin, Gyunggi-do (KR)

(73) Assignee: SAMSUNG ELECTRO-MECHANICS CO., LTD., Gyunggi-do (KR)

(21) Appl. No.: 13/409,791

(22) Filed: Mar. 1, 2012

(30) Foreign Application Priority Data
Dec. 5, 2011 (KR) 1020110129143

(51) Int. Cl. C23C 16/458; C23C 16/50

(52) U.S. Cl. 118/723 E; 118/729

(57) ABSTRACT

Disclosed herein is an apparatus for manufacturing a substrate. The apparatus for manufacturing a substrate includes: a reaction gas ejector ejecting reaction gas; a lift pin supporting the substrate and having a header contacting a rear surface of the substrate; and a support chuck having a lift pin insertion unit inserted with the lift pin and moving vertically and including a ring in a header insertion portion into which the header is inserted in the lift pin insertion unit.

### CROSS REFERENCE TO RELATED APPLICATION

This application claims the benefit of Korean Patent Application No. 10-2011-0129143, filed on Dec. 5, 2011, entitled “Apparatus for Manufacturing Substrate” which is hereby incorporated by reference in its entirety into this application.

### BACKGROUND OF THE INVENTION

1. Technical Field

The present invention relates to an apparatus for manufacturing a substrate.

2. Description of the Related Art

A lot of unit processes should be performed in order to manufacture a semiconductor device. The unit processes include for example, a deposition process, an etching process, an ion injection process, and the like. The unit processes are performed on a substrate or a wafer by using plasma. To this end, plasma chamber equipment is used. The plasma chamber equipment may be used to deposit or etch a material on the substrate by using the plasma.

In a plasma processing apparatus, the substrate is mounted on a support chuck constituting a lower electrode and high-frequency power is supplied to the support chuck, in a chamber to which reaction gas is supplied. Therefore, the plasma of the reaction gas is formed on the substrate and predetermined processing such as deposition or etching is performed on the substrate by using the plasma.

A plasma chamber may include a lift pin that allows the substrate to move vertically (Korean Patent Laid-Open Publication No. 10-2006-0067039). When the plasma chamber includes the lift pin, deformation such as bending of the substrate may occur by a prior process. When the deformation occurs, the substrate does not completely come in close contact with the support chuck. In this case, the reaction gas flows into a space in the support chuck where the lift pin moves, and as a result, arc is generated during a plasma process to cause an error of the substrate.

### SUMMARY OF THE INVENTION

The present invention has been made in an effort to provide an apparatus for manufacturing a substrate that prevents arc generated during a plasma process.

Further, the present invention has been made in an effort to provide an apparatus for manufacturing a substrate that improves reliability and productivity by preventing arc generated during the plasma process.

According to a first preferred embodiment of the present invention, there is a provided an apparatus for manufacturing a substrate, including: a reaction gas ejector ejecting reaction gas; a lift pin supporting the substrate and having a header contacting a rear surface of the substrate; and a support chuck having a lift pin insertion unit inserted with the lift pin and moving vertically and including a ring in a header insertion portion into which the header is inserted in the lift pin insertion unit.

The lift pin may include: a header of which the top contacts the rear surface of the substrate; and a supporter formed below the header and supporting the header.

The lift pin insertion unit may include: a header insertion portion into which the header is inserted; a supporter insertion portion connected with the center of the bottom of the header insertion portion and inserted with the supporter supporting the header; a ring insertion portion formed on the bottom of the header insertion portion and spaced apart from the supporter insertion portion by a predetermined gap; and a ring inserted into the ring insertion portion.

The ring inserted into the ring insertion portion may protrude from the bottom of the header insertion portion.

An anodized film may be formed on an inner wall of the lift pin insertion unit.

The apparatus for manufacturing a substrate may further include: a first electrode positioned to face the support chuck; and a second electrode positioned in the support chuck.

The apparatus for manufacturing a substrate may further include a lift positioned below the lift pin to move the lift pin vertically.

The apparatus for manufacturing a substrate may further include a reaction gas supplier supplying the reaction gas to the reaction gas ejector.

### BRIEF DESCRIPTION OF THE DRAWINGS

FIG. 1 is an exemplary diagram illustrating an apparatus for manufacturing a substrate according to a preferred embodiment of the present invention;

FIG. 2 is an exemplary diagram illustrating a cross section of a support chuck according to a preferred embodiment of the present invention;

FIG. 3 is an exemplary diagram illustrating a support chuck in which a lift pin protrudes according to a preferred embodiment of the present invention; and

FIG. 4 is an exemplary diagram illustrating a support chuck into which a lift pin is inserted according to a preferred embodiment of the present invention.

### DESCRIPTION OF THE PREFERRED EMBODIMENTS

Various features and advantages of the present invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings.

In describing the present invention, a detailed description of related known functions or configurations will be omitted so as not to obscure the subject of the present invention. Terms used in the specification, ‘first’, ‘second’, etc. can be used to describe various components, but the components are not to be construed as being limited to the terms. The terms are only used to differentiate one component from other components.

Hereinafter, an apparatus for manufacturing a substrate according to a preferred embodiment of the present invention will be described in detail with reference to the accompanying drawings.

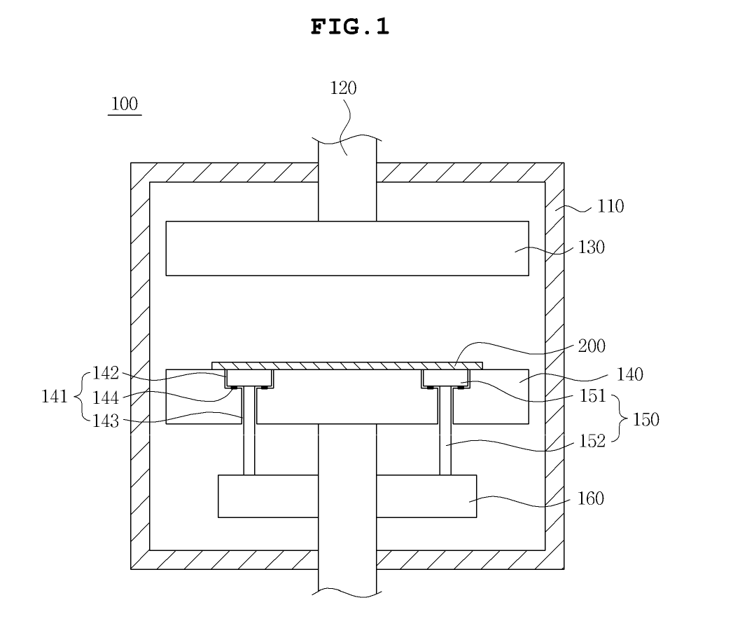

FIG. 1 is an exemplary diagram illustrating an apparatus for manufacturing a substrate according to a preferred embodiment of the present invention.

The substrate manufacturing apparatus 100 performs a predetermined process for depositing a deposition material on a substrate 200 by applying plasma.

Referring to FIG. 1, the substrate manufacturing apparatus 100 may include a process chamber 110, a reaction gas supplier 120, a reaction gas ejector 130, a support chuck 140, a lift pin 150 and a lift 160.

The process chamber 110 provides a space where the predetermined process using plasma is performed. The reaction gas ejector 130, the support chuck 140, the lift pin 150, and the lift 160 may be positioned in the process chamber 110.

The reaction gas supplier 120 may supply reaction gas to the reaction gas ejector 130 positioned in the process chamber 110.

The reaction gas ejector 130 may eject the reaction gas to the inside of the process chamber 110.

The substrate 200 to which the plasma process will be applied is seated on the support chuck 140. The support chuck 140 may include a heater (not shown) applying heat. The heater (not shown) supplies heat to the substrate 200 seated on the top of the support chuck 140 to improve deposition efficiency of the deposition material. The support chuck 140 includes a lift pin insertion unit 141 into which the lift pin 150 is inserted.

The lift pin insertion unit 141 may include a header insertion portion 142 and a supporter insertion portion 143.

A header 151 of the lift pin 150 is inserted into the header insertion portion 142. The header insertion portion 142 may have a shape corresponding to the header 151 of the lift pin 150. A ring 144 may be inserted into the bottom of the header insertion portion 142 contacting the header 151 of the lift pin 150. The ring 144 may be made of a material having elastic force. For example, the ring 144 may be made of rubber.

A supporter 152 supporting the header 151 of the lift pin 150 is inserted into the supporter insertion portion 143. The supporter insertion portion 143 may have a shape corresponding to the supporter 152 of the lift pin 150. The supporter insertion portion 143 is formed at the center of the header insertion portion 142 to be connected with the header insertion portion 142.

The anodized film may be formed on the support chuck 140 including the lift pin insertion portion 141. The anodized film may be formed outside the supporter chuck 140 and up to an inner wall of the lift pin insertion portion 141 formed in the support chuck 140.

The lift pin 150 supports the substrate 200. While the lift pin 150 moves vertically, the substrate 200 may be lifted to the top of the support chuck 140 or taken down and seat onto the support chuck 140. The lift pin 150 may include the header 151 and the supporter 152. The header 151 of the lift pin 150 contacts a rear surface of the substrate 200. The supporter 152 of the lift pin 150 is formed below the header 151 to support the header 151. The lift pin 150 may be penetratively inserted into the support chuck 140. The lift pin 150 formed as above may be inserted into the lift pin insertion portion 141 formed in the support chuck 140. The lift 160 may be connected with the bottom of the lift pin 150.

The lift 160 is connected with the bottom of the lift pin 150 to stably move the lift pin 150 vertically.

The substrate manufacturing apparatus 100 according to the preferred embodiment of the present invention may further include a first electrode (not shown) and a second electrode (not shown). The first electrode (not shown) and the second electrode (not shown) supply predetermined voltage for generating plasma. For example, the first electrode (not shown) may be formed to face the support chuck 140. That is, the first electrode (not shown) may be positioned above the reaction gas ejector 130 or the process chamber 110. Further, the second electrode (not shown) may be positioned in the support chuck 140. Any one of the first electrode (not shown) and the second electrode (not shown) may be connected with a voltage source supplying high-frequency voltage and the other one may be connected with a ground or a reference voltage source.

The anodized film may be formed in the process chamber 100. The anodized film may be formed on all of an inner wall of the process chamber 110, outer walls and inner walls of the reaction gas ejector 130, the support chuck 140, the lift pin 150, and the lift pin 160. Herein, components where the anodized film is formed are not limited thereto. That is, the anodized film may be formed on all of the outer walls and inner walls of all components formed in the process chamber 110 and exposed to the reaction gas.

In the substrate manufacturing apparatus according to the preferred embodiment of the present invention, the anodized film is formed on the outer wall of the process chamber and the outer walls and the inner walls of all the components in the process chamber to prevent arc generated by the reaction gas during the plasma process. Further, in the substrate manufacturing apparatus according to the preferred embodiment of the present invention, the ring is foamed at the lift pin insertion portion, and the anodized film is formed in the lift pin insertion portion to prevent arc from being generated in the lift pin insertion portion during the plasma process.

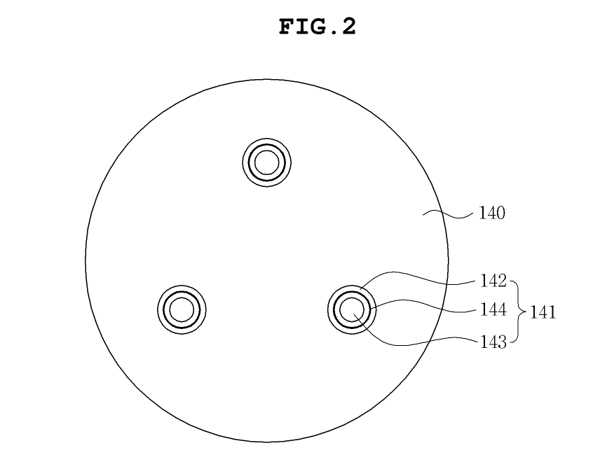

FIG. 2 is an exemplary diagram illustrating a cross section of a support chuck according to a preferred embodiment of the present invention.

Referring to FIG. 2, the top of the support chuck 140 may be checked. The support chuck 140 includes a plurality of lift pin insertion units 141. The lift pin 150 for supporting the substrate 200 of FIG. 1 seated on the top of the support chuck 140 is inserted into the lift pin insertion unit 141.

The lift pin insertion unit 141 may include the header insertion portion 142, the supporter insertion portion 143, and the ring 144.

The header 151 of the lift pin 150 is inserted into the header insertion portion 142. The header insertion portion 142 may have a shape corresponding to the header 151 of the lift pin 150. A diameter and a height of the header insertion portion 142 may be larger than the header 151 so that the header 51 of the lift pin 150 is repetitively inserted and protruded.

The supporter 152 of the lift pin 150 is inserted into the supporter insertion portion 143. The supporter insertion portion 143 may have a shape corresponding to the supporter 152 of the lift pin 150. For example, the supporter insertion portion 143 may be formed in the header insertion portion 142 to have a smaller diameter than the header insertion portion 142. The supporter insertion portion 143 may have a larger diameter than the supporter 152 so that the supporter 152 of the lift pin 150 moves vertically.

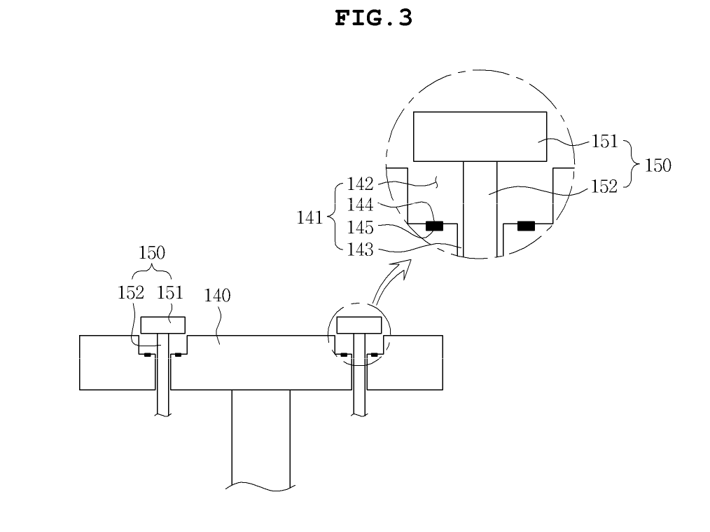

The ring 144 may be formed on the bottom of the header insertion portion 142. The ring 144 may be inserted into the ring insertion portion 145 of FIG. 3 formed on the bottom of the header insertion portion 142. The ring 144 may be formed outside the supporter insertion portion 143 while being formed on the bottom of the header insertion portion 142. That is, the ring 144 has a larger diameter than the supporter insertion portion 143 and a smaller diameter than the header insertion portion 142. The ring 144 may be formed to protrude onto the top from the bottom of the header insertion portion 142 while being inserted into the bottom of the header insertion portion 142. As such, when the header 151 of the lift pin 150 is inserted into the header insertion portion 142 by the ring 144 mounted on the bottom of the header insertion portion 142, outdoor air can be prevented from flowing into the lift pin insertion unit 141. Herein, the outdoor air may include the reaction gas ejected to the inside of the substrate manufacturing apparatus 100 of FIG. 1 where the support chuck 140 is positioned. The ring 144 may be made of a rubber material having elastic force.

The anodized film may be formed on the top of the support chuck 140 and the inner wall of the lift pin insertion unit 141 formed in the support chuck 140 according to the preferred embodiment of the present invention.

FIG. 3 is an exemplary diagram illustrating a support chuck in which a lift pin protrudes according to a preferred embodiment of the present invention.

Referring to FIG. 3, the cross section protrudes on the top of the support chuck 140 as the lift pin 150 moves upward.

The lift pin 150 may be moved upward by the lift 160. In this case, the lift pin 150 may lift the substrate 200 of FIG. 1 seated on the support chuck 140. Alternatively, the lift pin 150 may move upward in order to support the substrate 200 of FIG. 1 to be seated on the support chuck 140.

The header insertion portion 142 into which the header 151 of the lift pin 150 is inserted may be formed in the support chuck 140. The header insertion portion 142 may have a shape corresponding to the header 151 of the lift pin 150. Further, the supporter insertion portion 143 into which the supporter 152 of the lift pin 150 is inserted may be formed in the support chuck 140. The supporter insertion portion 143 may have a shape corresponding to the supporter 152 of the lift pin 150.

The ring may be inserted into the bottom of the header insertion portion 142. Further, the ring 144 may be spaced apart from an outer periphery of the supporter insertion portion 143 by a predetermined gap. That is, the ring 144 may be famed to surround the outer periphery of the supporter insertion portion 143. The ring 144 may be formed to be higher than the bottom of the header insertion portion 142 by a predetermined height. The ring 144 may be made of the rubber material having elastic force.

The anodized film may be formed on the outer walls of the lift pin 150 and the support chuck 140 and the inner wall of the lift pin insertion unit 141 formed in the support chuck 140 according to the preferred embodiment of the present invention.

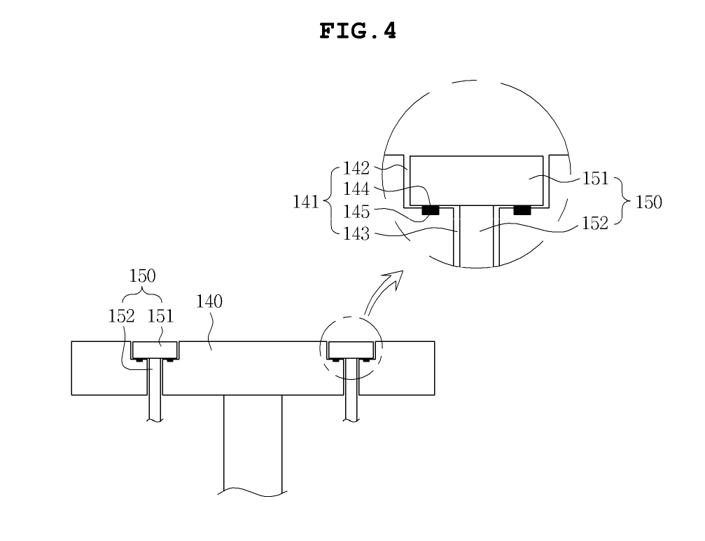

FIG. 4 is an exemplary diagram illustrating a support chuck into which a lift pin is inserted according to a preferred embodiment of the present invention.

Referring to FIG. 4, the cross section protrudes on the top of the support chuck 140 as the lift pin 150 moves upward.

The lift pin 150 may be moved downward by the lift 160. In this case, the lift pin 150 may seat the substrate 200 of FIG. 1 on the support chuck 140.

The header insertion portion 142 into which the header 151 of the lift pin 150 is inserted may be formed in the support chuck 140. The header insertion portion 142 may have a shape corresponding to the header 151 of the lift pin 150. Further, the supporter insertion portion 143 into which the supporter 152 of the lift pin 150 is inserted may be formed in the support chuck 140. The supporter insertion portion 143 may have a shape corresponding to the supporter 152 of the lift pin 150.

The ring may be inserted into the bottom of the header insertion portion 142. Further, the ring 144 may be spaced apart from an outer periphery of the supporter insertion portion 143 by a predetermined gap. That is, the ring 144 may be formed to surround the outer periphery of the supporter insertion portion 143. The ring 144 may be formed to be higher than the bottom of the header insertion portion 142 by a predetermined height. The ring 144 may be made of the rubber material having elastic force.

The lift pin insertion unit 141 has a diameter and a height larger than the lift pin 150 while having a shape corresponding to the lift pin 150 for vertical movement of the lift pin 150. That is, when the lift pin 150 is inserted into the lift pin insertion unit 141, the lift pin 150 cannot fully seal the lift pin insertion unit 141. Accordingly, the reaction gas may flow into the lift pin insertion unit 141 while the lift pin 150 is inserted. By the reaction gas that flows in as above, arc may be generated in the lift pin insertion unit 141 during the plasma process.

According to the preferred embodiment of the present invention, the ring 144 formed in the lift pin insertion unit 141 may seal the lift pin insertion unit 141 from the outside. That is, when the lift pin 150 is inserted into the lift pin insertion unit 141, the lift pin insertion unit 141 may be sealed by the ring 144 having elasticity, which protrudes from the bottom of the lift pin insertion unit 141 by a predetermined height. That is, when the lift pin 150 is inserted into the lift pin insertion unit 141 by the ring 144, the reaction gas can be prevented from flowing into the lift pin insertion unit 141. The reaction gas can be prevented from flowing into the lift pin insertion unit 141 by the ring 144 to prevent arc from being generated in the lift pin insertion unit 141 during the plasma process.

The anodized film may be formed on the outer walls of the lift pin 150 and the support chuck 140 and the inner wall of the lift pin insertion unit 141 formed in the support chuck 140 according to the preferred embodiment of the present invention.

That is, by the ring 144 and the inner wall of the lift pin insertion unit 141 formed on the anodized film, arc can be prevented from being generated in the lift pin insertion unit 141 by the reaction gas during the plasma process.

According to the preferred embodiments of the present invention, reaction gas can be prevented from flowing into a lift pin insertion unit by a ring formed by the lift pin insertion unit. Further, according to the preferred embodiments of the present invention, the reaction gas is prevented from flowing into the lift pin insertion unit by forming the ring in the lift pin insertion unit and arc generated in the lift pin insertion unit can be prevented during a plasma process by forming an anodized film. According to the preferred embodiments of the present invention, reliability and productivity in manufacturing the substrate 200 of FIG. 1 can be improved by preventing the arc in the lift pin insertion unit.

According to a preferred embodiment of the present invention, reaction gas can be prevented from flowing into a lift pin insertion unit by a ring formed by the lift pin insertion unit.

According to the preferred embodiment of the present invention, the reaction gas is prevented from flowing into the lift pin insertion unit by forming the ring in the lift pin insertion unit and arc generated in the lift pin insertion unit can be prevented during a plasma process by forming an anodized film.

According to the preferred embodiments of the present invention, reliability and productivity in manufacturing a substrate can be improved by preventing the arc in the lift pin insertion unit.

Although the present invention has been described in detail through detailed preferred embodiments, they are used to describe the present invention in detail and the apparatus for manufacturing the substrate according to the present invention is not limited thereto and it will be apparent that changes or modifications can be made by those skilled in the art within the spirit of the present invention.

Simple modifications or changes are included in the scope of the present invention and a detailed scope of the present invention will be apparent by the appended claims.

What is claimed is:

1. An apparatus for manufacturing a substrate, comprising:
a reaction gas ejector ejecting reaction gas;
a lift pin supporting the substrate and having a header contacting a rear surface of the substrate; and
a support chuck having a lift pin insertion unit inserted with the lift pin and moving vertically and including a ring in a header insertion portion into which the header is inserted in the lift pin insertion unit.

2. The apparatus as set forth in claim 1, wherein the lift pin includes:
a header of which the top contacts the rear surface of the substrate; and
a supporter formed below the header and supporting the header.

3. The apparatus as set forth in claim 1, wherein the lift pin insertion unit includes:
a header insertion portion into which the header is inserted;
a supporter insertion portion connected with the center of the bottom of the header insertion portion and inserted with the supporter supporting the header;
a ring insertion portion formed on the bottom of the header insertion portion and spaced apart from the supporter insertion portion by a predetermined gap; and
a ring inserted into the ring insertion portion.

4. The apparatus as set forth in claim 3, wherein the ring inserted into the ring insertion portion protrudes from the bottom of the header insertion portion.

5. The apparatus as set forth in claim 1, wherein an anodized film is formed on an inner wall of the lift pin insertion unit.

6. The apparatus as set forth in claim 1, further comprising:
a first electrode positioned to face the support chuck; and
a second electrode positioned in the support chuck.

7. The apparatus as set forth in claim 1, further comprising a lift positioned below the lift pin to move the lift pin vertically.

8. The apparatus as set forth in claim 1, further comprising a reaction gas supplier supplying the reaction gas to the reaction gas ejector.
